(19) United States
(12) Patent Application Publication
(10) Pub. No.: US 2007/0290193 A1
(43) Pub. Date: Dec. 20, 2007

(54) Field effect transistor devices and methods

(75) Inventor: John R. Tucker, Champaign, IL (US)

Correspondence Address: MARTIN NOVACK, 16355 VINTAGE OAKS LANE, DELRAY BEACH, FL, 33484, US

(73) Assignee: The Board Of Trustees Of The University Of Illinois

(21) Appl. No.: 11/654,376

(22) Filed: Jan. 17, 2007

Related U.S. Application Data
(60) Provisional application No. 60/759,724, filed on Jan. 18, 2006.

(51) Int. Cl. H01L 29/06; H01L 21/8238

(52) U.S. Cl. 257/22; 257/15; 438/212; 257/E29.005; 257/E21.632

(57) ABSTRACT

A field-effect transistor device is provided, including: a substrate; a vertically stacked layered semiconductor structure on the substrate including the following layers: a first quantum well layer having laterally spaced-apart drain and source regions that are each delta-doped with a dopant of a first conductivity type, the drain and source regions being laterally separated by a channel region; and a second quantum well layer vertically spaced from the first quantum well layer by a gate spacing layer, the second quantum well layer having a gate region, above the channel region, which is delta-doped with a dopant; and couplings for applying electrical potentials with respect to said source, drain, and gate regions.

### RELATED APPLICATION

Priority is claimed from U.S. Provisional Patent Application No. 60/759,724, filed Jan. 18, 2006, and said U.S. Provisional Patent Application is incorporated herein by reference.

### GOVERNMENT RIGHTS

This invention was made with Government support under Contract Number DMD19-01-1-0324 and DMD19-01-1-0579 awarded by the Defense Advanced Research Projects Agency. The Government has certain rights in the invention.

### FIELD OF THE INVENTION

This invention relates to transistor devices and, more particularly, to field effect transistor devices and methods for making field effect transistor devices.

### BACKGROUND OF THE INVENTION

Integrated circuits have been fabricated using essentially the same CMOS architecture for more than two decades. Devices have been made smaller, but the limit to scaling is in sight. The ultimate size of the MOSFET has now become less important than power dissipation and interconnects. As devices are made smaller, it becomes more of a challenge to run exceedingly tiny devices at GHz frequencies without the deleterious effects of heating. Neither molecular nor single-electronics devices offer a practical alternative in the foreseeable future.

A number of advances in Si-based material technologies have come to the fore, at least in the laboratory, during the past decade or so, including the following: (1) The use of Si/SiGe heterostructures has been employed in experimental field effect devices since the early 1990's, and in the mid 1990's heterolayer CMOS was proposed based on interleaved Si/SiGe quantum wells and demonstrated in part (see, for example A. Sadek et al., IEEE Trans. Electron Devices, 43(8), 1224-1242, 1996; M. Arafa et al., IEEE Electron Device Letters, Vol.17(3), 449-451, 1996). (2) The ability to pattern nanometer structures on a hydrogen passivated silicon surface, using a scanning tunneling microscope (STM) under ultrahigh vacuum (UHV) conditions, was also developed in the mid 1990's (see, for example, T.-C. Shen et al., Appl. Phys. Letters 66(8), 976-978, 1995, and T.-C. Shen, et al., Phys. Rev. Letters 78(7), 1271-1274, 1997). (3) The ultra-high vacuum (UHV) CVD growth process for Si/SiGe on H-terminated substrates (see B. S. Meyerson, Sci. Am., 1994, March, p. 62) was optimized to the point of commercial production of heterolayer bipolar transistor (HBT) chips in the latter 1990's using well-known modulation and planar (delta) doping techniques for the thin active layers.

Thus, Si/SiGe heterolayer technology and planar doping have both been known in the art for some time. In 1998, it was speculated that nanoscale patterning of planar doping could be realized by use of hydrogen as the mask for STM lithography, followed by selective adsorption of phosphine gas (PH₃) as a doping precursor and low temperature Si or SiGe overgrowth to activate the P donor pattern inside the crystal lattice (see my co-authored paper, J. R. Tucker and T. C. Shen, “Prospects For Atomically Ordered Device Structures Based On STM Lithography”, Solid State Electronics, Vol. 42(7-8), 1061-1067, 1998). In addition, it was also speculated that, if it should prove possible to integrate a projection e-beam system and/or large STM/AFM array into a UHV cluster tool, 3-dimensional heterolayer integrated circuits might be grown entirely in situ without breaking vacuum.

Subsequent experiments showed that unpatterned P delta-layers can be grown into silicon with a fully activated, ultra-dense carrier density of ˜1.7×10¹⁴ cm⁻², corresponding to the saturated ˜¼ monolayer density of PH₃ precursor admolecules as expected (see T.-C. Shen, et al., Appl. Phys. Lett. 80(9), 1580-1582, 2002; and L. Overbeck, et al., ibid, 81(17) 3197-3199, 2002). More recently, P-donor nanowires have been fabricated with STM e-beam lithography, and electrically characterized for widths in the 10-100 nm range (see T.-C. Shen, et al. J. Vac. Sci. Technol. B 22(6), 3182-3185, 2004; and F. J. Reuss, et al., Nano Letters 4(10), 1969-1973, 2004).

Systematic experiments on Si encapsulation of these ultra-dense P delta-layers have shown that vertical diffusion of P atoms above the PH₃ dopant plane can be limited to less than 1 nm, when the first ˜5 monolayers of Si are applied at room temperature followed by annealing up to ˜500 C (see L. Overbeck et al., Appl. Phys. Lett. 85(8), 1359-1361, 2004). These results indicate that a very high accuracy can be achieved in planar delta-doping of ˜5 nm thick quantum wells, and vertical stacks thereof, to create electronic devices.

Meanwhile, direct photodesorption of atomic hydrogen from the H-passivated Si(100) surface in ultra-high vacuum has been demonstrated with a 157 nm (7.9 eV) excimer laser source (see T. Vondrak and X.-Y. Zhu, J. Phys. Chem. B 103, 44892-4899, 1999). These findings offer a near-term possibility for selective nanopatterning of planar dopants by photolithography. However, in the ensuing years, to Applicant's knowledge, practical devices or methods using combinations of these techniques have not evolved to obtain the very high densities of field-effect transistor devices that are desired by the industry.

It is among the objects of the present invention to provide novel field effect transistor devices and methods that overcome drawbacks of prior approaches, and which permit very high device densities in an attractive architecture, including embodiments that can operate sub-threshold and at room temperature.

### SUMMARY OF THE INVENTION

In accordance with an embodiment of the invention, a field-effect transistor device is provided, comprising: a substrate; a vertically stacked layered semiconductor structure on said substrate including the following layers: a first quantum well layer having laterally spaced-apart drain and source regions that are each delta doped with a dopant of a first conductivity type, said drain and source regions being laterally separated by a channel region; and a second quantum well layer vertically spaced from said first quantum well layer by a gate spacing layer, said second quantum well layer having a gate region, above the channel region, which is delta-doped with a dopant; and electrical potentials being coupleable with respect to said source, drain, and gate regions. In an embodiment of the invention the gate region is delta-doped with a dopant of said first conductivity type, and the device further includes a back plane (e.g. for a ground plane) layer beneath and vertically spaced from the first quantum well layer, the back plane layer being delta doped with a dopant of opposite conductivity type to the first conductivity type. In this embodiment, the back-plane layer is a quantum well layer.

In a preferred embodiment of the invention, the first and second quantum well layers are strained layers, the first and second quantum well layers each have a thickness of about 5 nm, and the delta doped drain and source regions are doped with a planar sheet of dopant having a physical thickness of about 1 nm. In a form of this embodiment, there are further provided a third quantum well layer vertically spaced from the second quantum well layer, the third quantum well layer being delta doped with a dopant of the first conductivity type to form a local interconnect layer, and further comprising means for coupling a gate control potential with respect to the interconnect layer. In this embodiment, the third quantum well layer is spaced from the second quantum well layer by a tunneling region, and the interconnect tunneling region includes a plurality of tunneling vias. In accordance with another feature of this embodiment the third quantum well layer is doped with a dopant of the same conductivity type as the dopant of the gate layer, and the plurality of tunneling vias are vertically spaced delta doped sheets. The interconnect tunneling region further includes an overgate region disposed over the gate region, the overgate region being delta doped with a dopant of opposite conductivity type to the dopant of the gate region. Further, in this embodiment, additional tunneling vias comprised of vertically spaced delta dopant patterns of alternating polarity provide a way of coupling drain voltages in the first quantum well layer to interconnect regions in the third quantum well layer. Also in a form of this embodiment, a front-plane layer is provided above and vertically spaced from the interconnect layer, the front-plane layer comprising a fourth quantum well layer, delta doped with a dopant of opposite conductivity type to the conductivity type of the interconnect layer. In a further form of this embodiment, a gate control potential is applied via a gate conductor line in the first quantum well layer. In this form of the embodiment, the gate conductor line is oriented transversely to the channel region, and the overgate region has a lateral portion disposed over a portion of the gate conductor line.

In one preferred embodiment of the invention, the substrate and the layers of the layered structure are layers of SiₓGe₁₋ₓ, with at least some of the layers having a composition with x less than 1. In one form of this embodiment, the first and second quantum well layers are strained Si layers in adjacent layers of SiₓGe₁₋ₓ, and at least some of the different ones of said adjacent layers have different compositions of SiₓGe₁₋ₓ, with x less than 1.

In accordance with an embodiment of the method of the invention, a method is provided for making a field-effect transistor device, including the following steps: providing a substrate: depositing, on the substrate, a vertically stacked layered semiconductor structure, including the following steps: depositing a back-plane; depositing, vertically spaced from the back plane, a first quantum well layer having laterally spaced-apart drain and source regions that are each delta doped with a dopant of a first conductivity type, so that said drain and source regions are laterally separated by a channel region; depositing, vertically spaced from said first quantum well layer by a gate spacing layer, a second quantum well layer having a gate region, above the channel region, which is delta-doped with a dopant of said first conductivity type; and providing couplings for applying electrical potentials with respect to the source, drain, and gate regions. In a form of this embodiment of the method of the invention, the step of depositing a first quantum well layer having laterally spaced-apart drain and source regions that are each delta doped with a dopant of a first conductivity type, so that said drain and source regions are laterally separated by a channel region, includes the following steps: depositing a host semiconductor layer on said back-plane layer; depositing an initial strained semiconductor layer on the host layer; patterning source and drain region patterns on said initial strained semiconductor layer; forming source and drain regions by selectively applying sheets of dopant to the source and drain region patterns; and depositing a further strained semiconductor layer over the initial strained semiconductor layer. Also in a form of this embodiment of the method of the invention, the step of depositing a second quantum well layer having a gate region, above the channel region, which is delta-doped with a dopant of said first conductivity type, comprises: depositing an initial strained semiconductor layer on the gate spacing layer; patterning a gate region pattern on the initial strained semiconductor layer on said gate spacing layer; forming said gate region by selectively applying a sheet of dopant to said gate region pattern; and depositing a further strained semiconductor layer over the initial strained semiconductor layer on said gate spacing layer.

Another embodiment of the method of the invention comprises a method for making a multiplicity of field-effect transistor devices, including the following steps: providing a substrate; depositing, on the substrate, a vertically stacked layered structure, including the following steps: depositing a back-plane; depositing, vertically spaced from the ground plane, a first quantum well layer having a multiplicity of laterally spaced-apart pairs of drain and source regions that are each delta doped with a dopant of a first conductivity type, so that each said pair of drain and source regions are laterally separated by respective ones of a multiplicity of channel regions; depositing, vertically spaced from the first quantum well layer by a gate spacing layer, a second quantum well layer having a multiplicity of gate regions, above the respective multiplicity of channel regions, which are each delta-doped with a dopant of said first conductivity type; and providing couplings for applying electrical potentials with respect to said source, drain, and gate regions.

The size of the devices in embodiments hereof are greatly reduced by eliminating all of the conventional means for isolation—implanted wells and several applications of amorphous dielectrics—in favor of built-in potentials between planar delta-doping layers of opposite conductivity type. Local connections between adjacent devices are also greatly simplified and reduced in area. Accordingly, very large device densities, of the order of ˜1/(100 nm)²=10¹⁰ cm⁻² can become achievable. Embodiments hereof can operate subthreshold and at room temperature.

Further features and advantages of the invention will become more readily apparent from the following detailed description when taken in conjunction with the accompanying drawings.

### BRIEF DESCRIPTION OF THE DRAWINGS

FIG. 1 is a simplified cross-sectional diagram of a field-effect transistor device that illustrates a principle of the invention.

FIG. 2 is a band diagram for the FIG. 1 device.

FIG. 3 shows a simplified top plan view of multiple field-effect devices.

FIG. 4 is a cross-sectional view of a field effect transistor device in accordance with the invention, and which can be made by practicing a method in accordance with an embodiment of the invention. The parameters in this example are representative of those that would be used for subthreshold logic and/or analog circuits at room temperature.

FIG. 5 is a band diagram for the device of FIG. 4.

FIG. 6 is a cross-sectional view of a field effect transistor device in accordance with another embodiment the invention, and which can be made by practicing a method in accordance with an embodiment of the invention.

FIG. 7a is a top plan view and FIG. 7b is a cross section band diagram showing an embodiment of the overgate for the FIG. 6 embodiment.

FIG. 8 is a band diagram showing carrier confinement below the overgate.

FIG. 9 is a band diagram illustrating the concept of a tunneling via.

FIGS. 10 and 11 are diagrams relating to variations of the device of FIG. 6

FIG. 12 is a diagram illustrating an in-plane cross-over pertaining to the variations in FIGS. 10 and 11.

FIG. 13 is a diagram illustrating a CMOS-type architecture comprised of interleaved and complementary quantum wells.

FIG. 14 is a band diagram relating to the embodiment of FIG. 13.

FIG. 15, which includes FIGS. 15A, 15B, 15C, and 15D, placed one below another, is a flow diagram of a routine for practicing an embodiment of the method of the invention.

### DETAILED DESCRIPTION

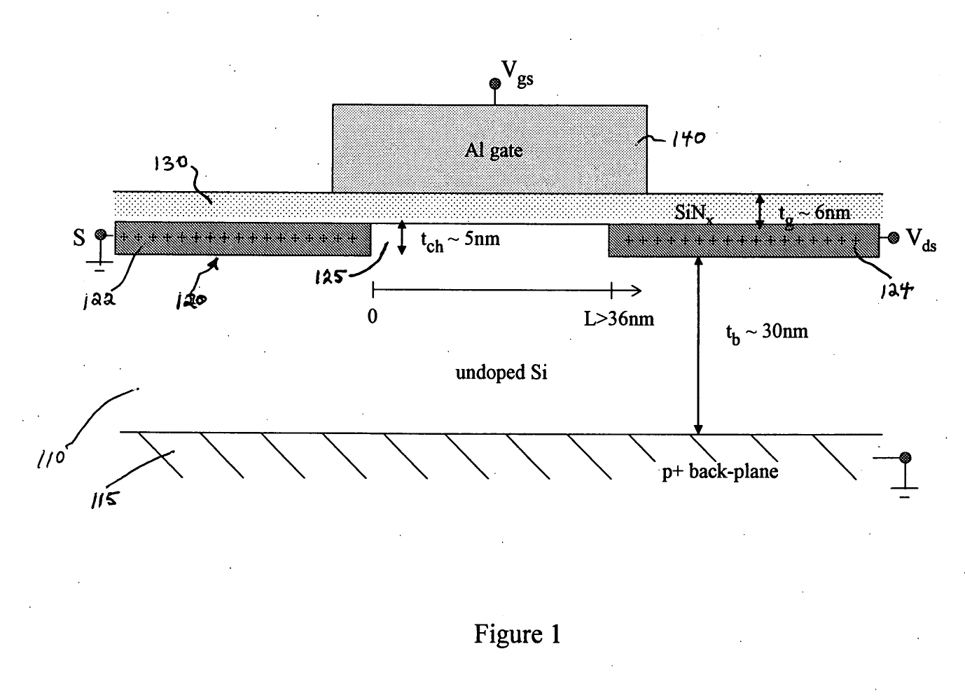

FIG. 1 illustrates a principle of the invention by showing an embodiment of a field-effect transistor device which has the source, drain, channel, and associated “wiring” (e.g., terminal couplings to source and drain) fabricated by patterning an ultra dense delta-doped layer within an epitaxially deposited semiconductor layer. In this simplified embodiment, an undoped silicon body 110 has a p+ back-plane 115 on its bottom surface. The epitaxially deposited layer 120 has, in this example, about 2.5 nm of Si on which is deposited, in patterned source (122) and drain (124) regions of the plane, ultra dense delta-doped layers of, in this example, n+ dopant, overgrown by another ˜2.5 nm of Si. Accordingly, the layer 120, in this embodiment, has a thickness of ˜5 nm, as seen at the channel region 125, with t_{ch} being about 5 nm. The channel length, L, in this example, is about 36 nm. Also, in this simplified embodiment, a gate insulator layer (130) of about 6 nm of SiNₓ is grown over the layer 120, followed by a patterned gate electrode 140, for example of Al. In this example, the back-plane potential is held in common with the grounded source reference potential, the drain potential is designated V_{ds}, and the gate potential is designated V_{gs}.

The general form of the device of FIG. 1 is similar to that of a thin-body silicon-on-insulator (SOI) n-MOSFET, apart from the delta-doped source/drain. Detailed band calculations on a saturated ˜¼ ML P delta-layer in unstrained Si predict a very deep potential well and a confinement potential of ˜100 meV for electrons at the Fermi level (see G. Qian, Y.-C. Chang, J. R. Tucker, Phys. Rev. B 71, 2005, p. 045309). Calculated thickness of the electron subband wavefunctions is ˜5 nm or less in the growth direction. The thickness of the undoped FET channel is adjusted to this value by hard confinement at the interface with a top dielectric ˜2.5 nm above the doping plane, and by the large built-in electric field of the p+ back-plane below.

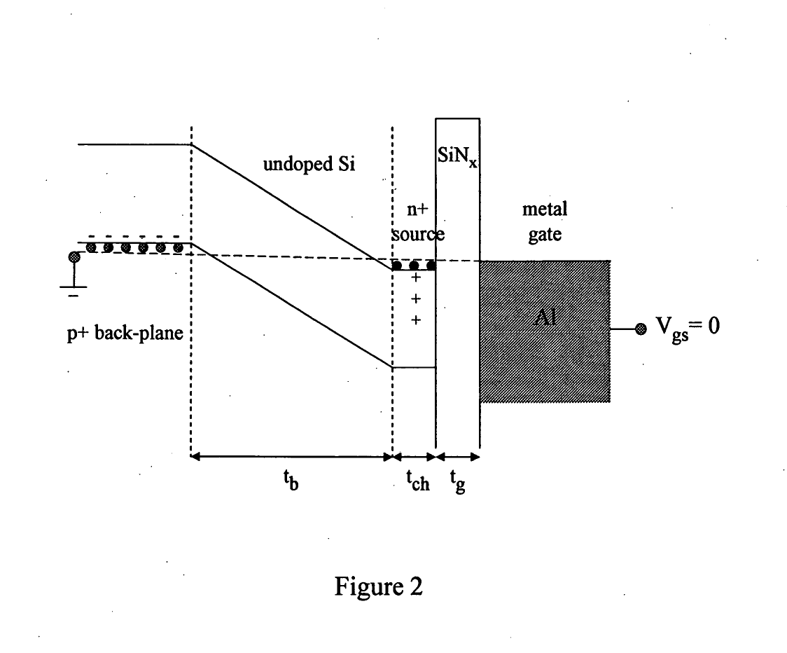

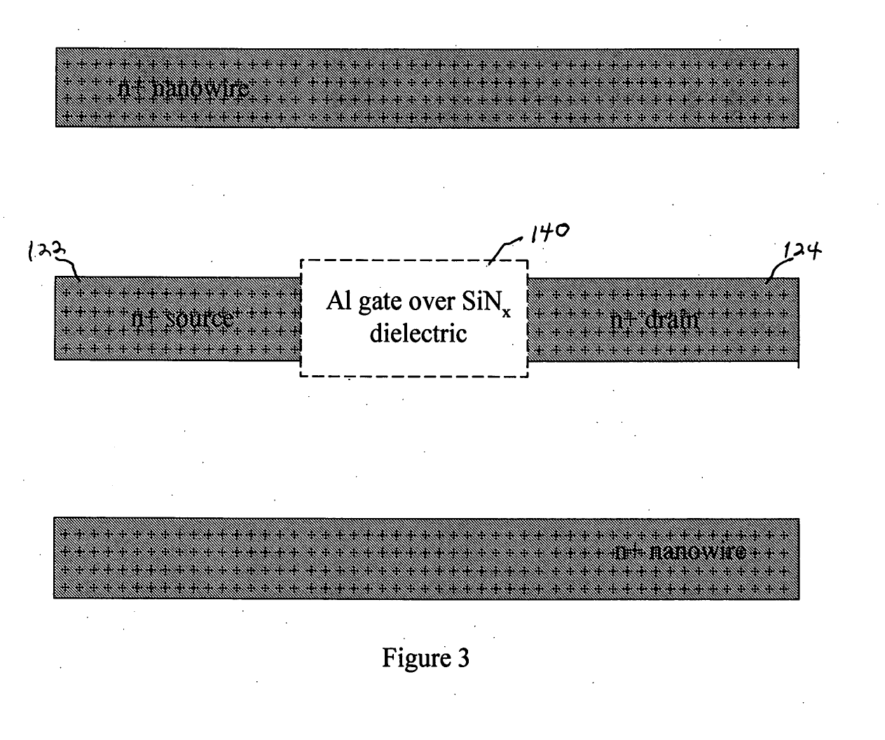

FIG. 2 sketches the cross sectional band diagram for this structure. The top-gate is taken to be Al metal for purposes of Illustration, yielding a near zero flat-band voltage. The gate dielectric is grown at low temperature in order to avoid diffusion of dopants in the patterned P delta-layer. In an example of this embodiment, a room-temperature Jet Vapor Deposition (JVD) process for thin SiNₓ films is used (see T.-P. Ma, IEEE Trans. Electron Devices 45(3) 1998, pp. 680-690). The grounded p+ back-plane below the channel serves two purposes. First, the large built-in potential relative to the n+ delta-layer acts to confine electrons at the bottom of the ˜6 nm thick channel. Secondly, the depth of the back plane, t_{b}, relative to the dielectric thickness, t_{g}, determines the height of the ‘off-state’ barrier between the source and drain at zero gate voltage, V_{gs}=0, and thereby the positive threshold voltage that must be applied to eliminate that barrier and turn the device ‘on’. At room temperature, in an example hereof, the grounded p+ back-plane is positioned at t_{b}˜30 nm below the channel to achieve a threshold gate voltage of ˜0.25V. The minimum channel length for this device is estimated to be L_{G}˜36 nm, in conjunction with a ˜6 nm-thick SiNₓ dielectric film. The relatively large ˜1.1 eV built-in potential of the p+ back-plane also guarantees that parallel n+ nanowires in the doping plane will be isolated from one another in un-gated regions at a spacing of ˜40 nm. FIG. 3 shows a top plan view of parallel nanowires of this example.

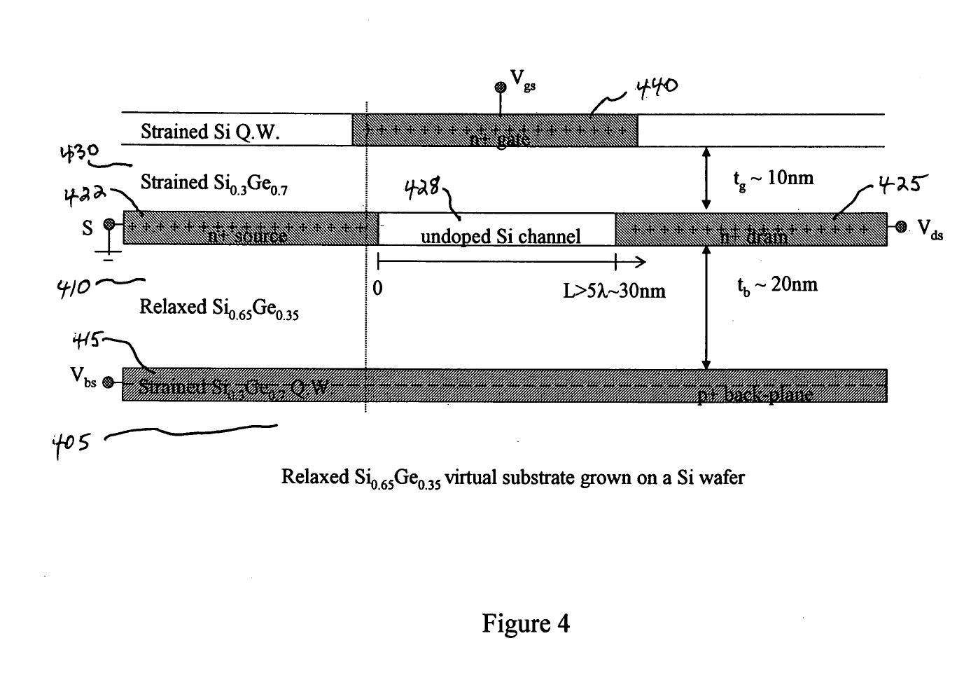

FIG. 4 illustrates a fully-epitaxial embodiment of the invention in which the channel, gate, and back-plane are all confined in separate quantum wells of ˜5 nm thickness, and doped by selective patterning of ultra-dense delta-layers. In one example of the embodiment of FIG. 4, the quantum wells are Si/SiGe heterolayer quantum wells, and the doping is implemented with ultra-dense phosphorus (P) and boron (B) dopant delta-layers. FIG. 4 shows a cross-section of an n-FET, it being understood that a p-FET version can be fabricated in similar manner. In the diagram of FIG. 4, a relaxed Si_{0.65}Ge_{0.35} (on Si) virtual substrate 405 is provided and has, deposited epitaxially grown thereon, a strained Si_{0.3}Ge_{0.7} quantum well 415, delta-doped p+ to form a back-plane layer; a body layer 410 of unstrained Si_{0.65}Ge_{0.35}; a strained Si quantum well layer in which are formed a n+ delta-doped source region 422, an undoped channel region 428, and a n+ delta-doped drain region 425 (formed, for example, in a manner similar to the corresponding FIG. 1 regions); a strained high-Ge content Si_{0.3}Ge_{0.7} gate insulator region 430; and a strained Si quantum well layer in which is formed an n+ gate region 440.

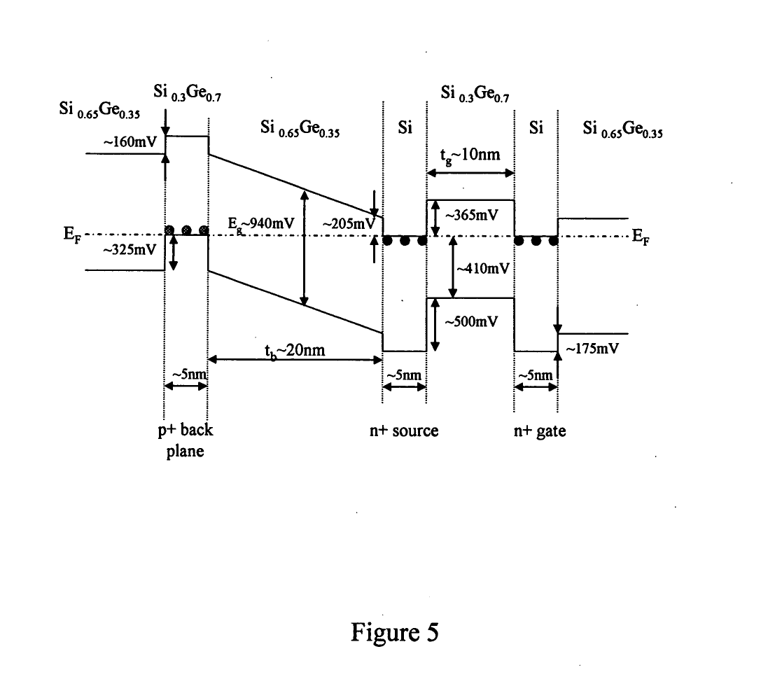

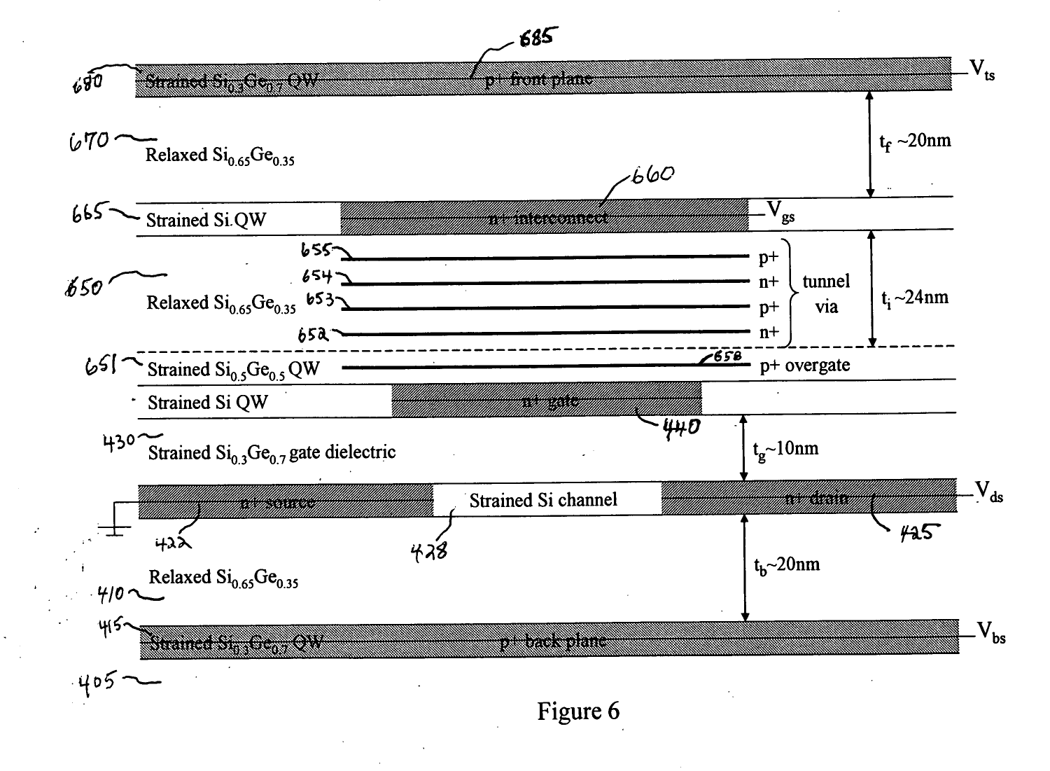

The band diagram for the FIG. 4 device is shown in FIG. 5. Vertical confinement for electrons in the active n+ delta-layers is achieved by growing the source/drain and gate patterns into the center of strained Si quantum wells (QWs). Beneath the n+ channel is the p+ delta-layer back-plane 415, grown into a strained, high-Ge content, Si_{0.3}Ge_{0.7} QW that provides vertical confinement for holes. A second p+ front-plane (not shown) can be included above the n+ gate 440 to insure in-plane isolation in both gate and channel active layers. Electrical connections between the n+ active layers can be made by interrupting growth in the middle of the intervening SiGe layer (one or more times), and patterning a p+ contact array (similar to the tunnel via in FIG. 6 below) before resuming growth. Alternatively, inter-level contacts could be implemented capacitively, in which case those gates will float. Floating capacitive gates have previously been proposed for neural network applications and demonstrated with conventional MOSFET technology (see T. Shibata and T. Ohmi, IEEE Tars. Electron Devices 39(6) 1992, pp. 1444-1455). External contacts can be made, for example, by growing selectively patterned metal silicide layers into delta-doped nanowire in/outputs at very low temperatures of ˜350 C.

The SiGe virtual substrate is grown on a Si wafer using a grading technique that reduces threading dislocation densities from ˜10¹¹ cm⁻² at the underlying Si interface to ˜10⁵ cm⁻² in the fully relaxed SiGe top layer. A thin layer of the relaxed SiGe can then be transferred onto oxide by wafer bonding and etch back (see, e.g., G. Taraschi et al., J. Vac. Sci. Technol. B 20(2) 725, 2002). Virtual substrates of this kind are sufficient for testing field effect transistors; and research is currently underway to reduce dislocation densities for future use in conventional CMOS. When employed with selectively patterned ultra-dense delta-layers, MBE (molecular beam epitaxy) techniques may be used to lower the growth temperatures for the top active heterolayers.

The cross sectional band diagram in FIG. 5 uses published valence band offsets in this heterolayer system (see C. Ni Chleirigh et al, ECS Proceedings PV 2004-7 (Electrochemical Society, Pennington, N.J., 2004), pp. 99-110) and estimated energy gaps (see H. M. Nayfeh et al., IEEE Trans. Electron Devices, 51(12), 2069, 2004; R. People and J. Bean, Appl. Phys. Lett. 48, 538, 1986; and Braunstein et al., Phys. Rev. 109, 695, 1958). In this implementation, the relaxed Si_{0.65}Ge_{0.35} host crystal will serve as a dielectric between the p+ back plane 415 and the bottom sides of the n+ source, drain, and channel. A strained high-Ge Si_{0.3}Ge_{0.7} layer 430 (of the same composition as the p+ QW) will serve as a dielectric barrier of ˜365 meV between the top-side of the channel and the n+ gate. Preliminary calculations indicate that tunneling between the channel and the gate is effectively eliminated for a barrier thickness of t_{g}˜10 nm. The small ˜365 meV height of this barrier, compared to normal dielectrics, will limit supply voltages to ˜300 mV and operating temperatures for conventional logic to T˜100K. However, it is important to note that subthreshold operation of both logic and analog circuits is possible at and somewhat above room temperature.

According to FIG. 5, the built-in potential between the p+ ground plane and the n+ source is ˜410 mV, minus the sum of the binding energies for both p+ and n+ delta-layers. These binding energies are expected to be much lower than the ˜100 meV estimate for a P delta-layer in unstrained Si, due to lifting of valley degeneracy, and can be neglected for rough estimates. Applying a negative bias voltage, V_{bs}, to the back gate will increase the in-plane isolation for the n+ active layers over the approximate built-in value of ˜410 mV.

A simplified FET model has often been employed to estimate the characteristics of thin-body SOI and double-gate devices, based on a parabolic approximation for the vertical variation of electrical potential across a thin, well-confined channel (see, for example, K. Young, IEEE Trans. Electron Devices, 36(3), 504, 1989; R.-H. Yan, et al., IEEE Trans. Electron Devices, 39(7), 1704, 1992). This model is easily adapted to a device of the type shown in FIG. 4. The barrier height, Φ_{B}, presented to electrons entering the channel from the grounded source is determined by a linear average of the top gate and bottom back-plane voltages relative to flat band, according to their vertical distance from the channel. The prediction in a long-channel device is:

$${Φ}_{B} = \frac{1}{1 + r} \{ ( {V}_{FB , bs} - {V}_{bs} ) + r ( {V}_{FB , gs} - {V}_{gs} ) \} , where r = {t}_{b} / {t}_{g} .$$

For the n-FET in FIG. 5, the flat-band voltages are:
V_{FB,bs}=410 mV and V_{FB,gs}32 0

The applied gate voltage, V_{gs}, must be smaller than the gate dielectric barrier of ˜365 meV in order to prevent field-induced tunneling from gate to source and channel. Accordingly, the maximum supply voltage is taken to be V_{DD}=300 mV in this example. A reverse bias of V_{bs}=−230 mV can be applied to the p+ back-plane to raise the total band-bending and in-plane isolation for a grounded n+ source, (V_{FB,bs}−V_{bs}), to 640 mV. A positively biased n+ drain will then see an increase in band bending, relative to the p+ back-plane, up to a limit of 940 mV. This limit is defined by the energy gap of the relaxed Si_{0.65}Ge_{0.35} layer above the p+ back plane, so avalanche breakdown can be avoided.

The magnitude of thermally generated leakage current for this reverse biased p+-i-n+ back-plane structure needs to be characterized to determine if this poses a problem. The expectation is that reverse thermal leakage here will be much smaller than for conventional p-n junctions. Thermally generated electrons diffusing toward the p+ back-plane from below will encounter a sizeable ˜160 mV barrier before they reach the i drift region; and minority holes diffusing toward the junction from above the n+ side will encounter a series of even higher barriers. Also, the thin ˜20 nm i layer itself provides only a very small volume for thermal generation of electron-hole pairs within the drift region.

Employing the above parameters, the channel barrier height, Φ_{B}, can be estimated as a function of the gate voltage, V_{gs}, using the gate dielectric thickness ratio, r=t_{b}/t_{g}=2.0, in this example of the present embodiment, for t_{b}=20 nm and t_{g}=10 nm:
Φ_{b}=214 mV−V_{gs}/1.5, for 0<V_{gs}<300 mV
Here, the channel barrier approaches zero at a gate voltage of 320 mV. Under these conditions, the entire subthreshold region is covered by the gate voltage range 0<V_{gs}<V_{DD}=300 mV.

Accordingly, the drain current in this device will then take the form:
I_{ds}=I₀exp(V_{gs}/Vₜ)
where I₀ represents thermal emission over the maximum ‘off state’ barrier, Φ_{B}^{max}=214 mV, and V_{T}=kT(1+r)/r represents the effective thermal voltage. At room temperature, V_{T}=39 mV; and the range of subthreshold drain current is approximately 2.2×10³ for V_{DD}=300 mV.

The longitudinal behavior of the channel potential between source and drain is governed by a combination of two characteristic lengths associated with the top- and bottom-gates, which, for this example of the present embodiment, are:
λ_{g}=\sqrt{t_{ch}·t_{g}}≈\sqrt{5·10}≈7.1 nm, λ_{b}=\sqrt{t_{ch}·t_{b}}≈\sqrt{5·20}≈10 nm
The combined result is 1/λ²=1/λ_{g}²+1/λ_{b}², yielding a channel characteristic length λ≈5.8 nm. The standard criterion for long-channel behavior is a channel length L_{G}>5λ. Channel lengths for this example will therefore be L_{G}˜30 nm or more. This is somewhat longer than the gate lengths that will be realized at the limit of conventional CMOS. Nevertheless, the overall size of the these devices is greatly reduced by eliminating all of the conventional means for isolation - - - implanted wells, trench isolation, sidewalls for gates and several additional applications of amorphous dielectrics for contact vias, interconnects, etc. - - - in favor of built-in potentials. Local connections between adjacent devices are also greatly simplified and reduced in area. By these means, very large device densities, of the order of ˜1/(100 nm)²=10¹⁰ cm⁻² can become achievable. Another advantageous feature of the architecture of this embodiment is that low-field carrier mobilities in the strained quantum wells are nearly twice those in unstrained silicon, e.g. ˜2500 and 800 cm² /Vs for electrons and holes, respectively (A. Sadek, et al., IEEE electron Devices, 43(8), 1224, 1996). Transport along the L_{G}˜30 nm channel is expected to be quasi-ballistic, and subthreshold saturation should occur for drain voltages above 2 kT˜50 mV.

A rough estimate for the minimum thermal emission drain current can be made by treating the n+ source as a metal wire of thickness t_{ch}=5 nm:

$$\begin{matrix}{I}_{0} \approx ( {t}_{ch} W ) {AT}^{2} exp ( - {Φ}_{B}^{0} / kT ) \\ \approx 3 n A ⨯ ( W / 100 n m ) , for T = 300 K , {Φ}_{B}^{0} = 214 meV , m * \approx 0.2 {m}_{o} s\end{matrix}$$

The estimated maximum subthreshold drain current then becomes:
Iₘₐₓ=I₀exp(V_{DD}/Vₜ)≈6.6 μA×(W/100 nm)
For subthreshold operation, the load capacitance will be dominated by the drain output line capacitance over the p+ back-plane to the next gate:
C_{bp}≈ε_{SiGe}/t_{b}≈5.75×10⁻⁷ F/cm², for t_{b}=20 nm
C_{Line}≈C_{bp}WL≈57aF×(W/100 nm)×(L/100 nm)
where W and L represent the width and length of said output line. A relaxed SiGe host lattice can support the growth of confining quantum wells up to a depth greater than 350 mV for both electrons and holes, as sketched in FIG. 5. Because of this, parameters similar to the n-FET discussed above can be expected for a complementary p-FET.

Combining the rough estimates detailed above yields a subthreshold inverter delay time:
t_{d}≈C_{Line}V_{DD}/Iₘₐₓ≈2.6 ps×(L/100 nm)
and a switching energy:
E_{SW}≈C_{Line}V_{DD}²≈5 aJ×(W/100 nm)×(L/100 nm)
IBM extrapolations of energy-delay data for conventional CMOS down to a hypothetical 10 nm node predict that subthreshold and conventional inverter performance will converge toward the 10 aJ-10 ps range (E. J. Nowak, IBM J. Res.& Dev. 46(2/3), 169, 2002). Rough estimates made here indicate that epitaxial nanowire devices could approach those energy-delay targets for ‘ultimate scaling’, with much larger linewidths in the 50-100 nm range defined by 157 nm excimer lithography. Further advances in lithography could reduce dimensions toward the atomic level, opening new possibilities for integrated circuits based on quantum principles, e.g. quantum cellular automatons (see G. L. Snider, et al., J. Appl. Phys. 85(8), 4283-4285, 1998) and Si-based quantum computers (see B. E. Kane, Nature 393, 133-137, 1998).

An objective here is not to supplant conventional CMOS, but to reach toward other goals that might not otherwise be achieved. One possible application may be to develop an integrated circuit process for multilevel, analog/digital architectures that can support biological-inspired functionality (see, e.g., C. Mead, Analog VLSI and Neural Systems, Addison-Wesley, 1989). A significant advantage of this invention is that the field effect transistor shown in FIG. 4 will have a threshold voltage determined by the ratio of vertical distances from the channel to back-plane and gate. As the thickness for these layers can be controlled to atomic accuracy in MBE growth, unprecedented uniformity in threshold voltage can be expected. Another significant advantage is the possibility for interconnection between layers at the device level, greatly increasing connectivity of the overall architecture. Both of these are central to opening new possibilities for analog as well as digital circuits. A second possible application may be to provide the link between conventional electronics and quantum computational modalities, including those mentioned above.

FIG. 6 shows further details of the FIG. 4 device (where like reference numerals represent corresponding or similar elements) in accordance with an embodiment of a complete n-FET. (The complete p-FET will have opposite conductivity types throughout.) Above the n+ gate 440, and spaced therefrom by a host Si_{0.65}Ge_{0.35} layer 650, is a somewhat longer n+ interconnect layer 660 in a strained Si layer 665, with a total separation from the gate of tᵢ˜30 nm. These two levels are connected through a tunnel via comprised of an alternating sequence of n+ and p+ planar doping patterns 652, 653, 654, and 655, grown at regular intervals into the host crystal. Spaced from the n+ interconnect by Si_{0.65}Ge_{0.35} layer 670, is a p+ front-plane 685, in a strained Si_{0.3}Ge_{0.7} layer 680, held at the same negative bias as the p+ back-plane of ˜0.23V in the above example. This p+ front-plane layer can be placed somewhat closer than the ˜20 nm spacing between the n+ source/drain level and the p+ back-plane. The built-in potential of 410 mV for the p+ back- and front-planes to grounded n+ lines is enhanced to 640 mV by the ˜0.23V negative bias, and to 940 mV for n+ lines at V_{DD}=300 mV, which is more than sufficient, and the minimum spacing between n+ lines within the interconnect and source/drain levels can be estimated at ˜40 nm using the double-gate model described above.

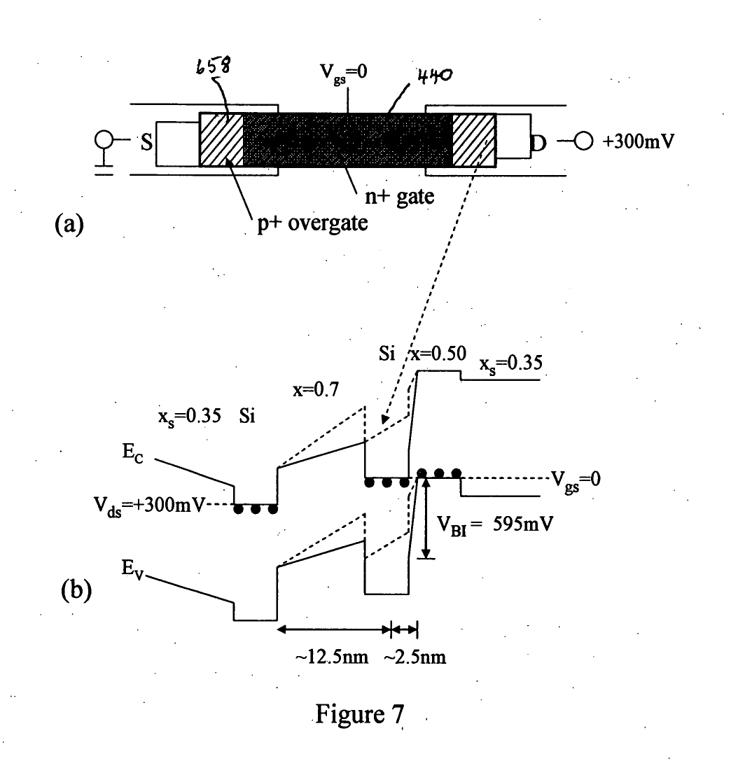

Isolation at the gate level is more challenging. The n+ gate 440 overlaps with the n+ source and drain in order to provide barrier control over the entire channel length. When the drain 425 is positively biased with respect to the n+ gate, V_{ds}>V_{gs}, gate electrons can leak out laterally over the drain wire beyond the gate's doping pattern (while still confined in the vertical direction by the quantum well). In accordance with a feature hereof, solution to this problem is to insert a p+ delta-layer overgate 658 of the same width into a strained Si_{0.50}Ge_{0.50} layer 651 of ˜5 nm thickness, directly above the n+ gate pattern, thereby completing the tunnel via contact to the interconnect level. The length of the p+overgate 658 is extended ˜12 nm beyond that of the n+ gate over both source and drain, as seen in FIG. 7a in top view. The worst case for in-plane n+ gate leakage, V_{gs}=0 and V_{ds}=+300 mV, is illustrated by the band diagram in FIG. 7b. Solid lines show electrons within the grounded n+ gate pattern, 300 meV above those in the drain. Without the p+ overgate, the gate-level electron potential would fall lower toward the drain level beyond the n+ gate pattern, causing leakage of gate electrons over the drain wire (while still confined in the vertical direction). The built-in potential of 595 mV for the p+ overgate relative to the n+ gate will provide a total band-bending of 895 mV to the positively biased n+ drain in the ˜12 nm overhang region, when V_{gs}=0 and V_{ds}=+300 mV, substantially raising the gate level electron potential as indicated by the dotted line in FIG. 7b. A rough estimate indicates that the gate-level channel potential will be raised by approximately ˜440 mV (at the well center) across the ˜12 nm overhang region, thereby confining mobile electrons to the n+ gate doping pattern. Containment at the sides of the n+ gate pattern is also provided by the p+ overgate, in addition to the p+ back-plane as for source and drain.

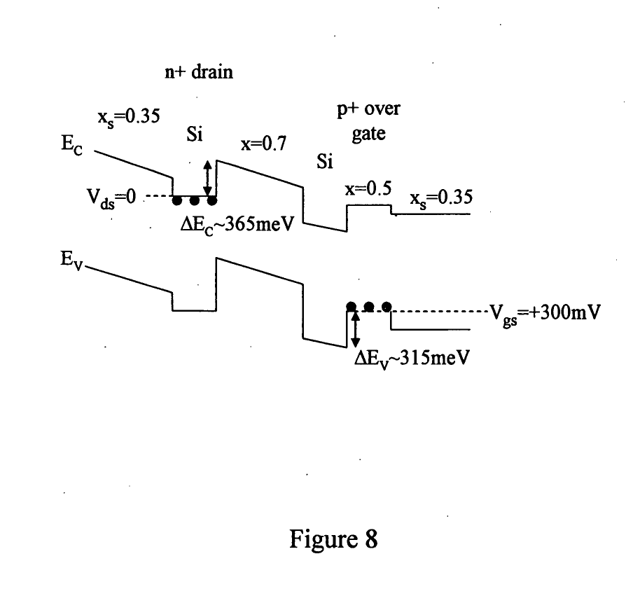

A second problem then arises when the drain or source is negative with respect to gate voltage, as illustrated FIG. 8. In this case, the confining barrier for holes below the p+ overgate will be reduced in the overhang region toward the valence band discontinuity of ˜315 mV at the interface of the strained Si_{0.50}Ge_{0.50} layer 651 with the strained Si n+ gate-level quantum well. This ˜315 mV p-barrier should be sufficient to limit gate leakage from the ˜12 nm p+ overgate regions. Had the p+ overgate been placed into the host Si_{0.65}Ge_{0.35} layer 650 along with the tunnel via (see FIG. 6), the valence band discontinuity to the strained Si n-well would be only ˜175 mV, as can be seen in FIG. 5, and much too small for room temperature operation.

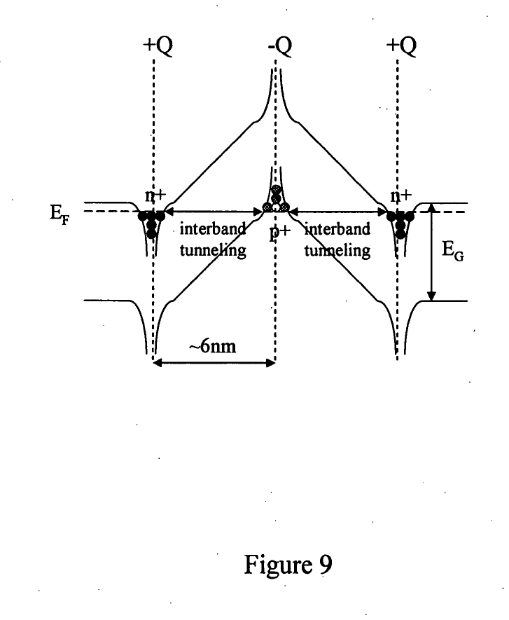

As above indicated, the tunnel connection from the n+ gate to the n+ interconnect level for this embodiment is completed by growing a series of alternating n+ and p+ planar doping patterns 652, 653, 654, and 655, of the same dimensions and grown at regular intervals of ˜6 nm into the host layer 650, as shown in FIG. 6, to form an ohmic contact. The built-in potential between the adjacent p+ and n+ delta-layer patterns is approximately equal to the 940 meV energy gap of the relaxed Si_{0.7}Ge_{0.3} host crystal, as indicated in the band diagram of FIG. 9. When positioned vertically above and below one another, very large fringing electric fields will deplete a small region along the perimeter of each patterned layer within the stack, confining mobile carriers to the interior. The width of these depletion regions will be small due to the extremely large delta-doping densities of ˜1-2×10¹⁴ cm⁻². Within the undepleted core, good ohmic contact will be established between the adjacent n+ and p+ patterns for a vertical separation of approximately ˜6 nm in the growth direction, by the mechanism of interband tunneling illustrated in FIG. 9. The polarization charge induced by the built-in potential between layer cores at ˜6 nm separation is approximately Q˜1×1013e/cm², only ˜10 percent of the mobile carrier density within the interior of the patterns.

Both the magnitude of the self-confining potential at the edges of the alternating n+ and p+ delta-layer stack and its resistance will depend on the precise vertical spacing. The parameters of this embodiment are expected to work well with a self-confinement equal to a sizeable fraction of the ˜940 mV built-in potential. However, it should be noted that the built-in potential between the top p+ via layer and the n+ interconnect is reduced to ˜735 mV, and to ˜800 mV between the bottom n+ via layer and the p+ overgate.

The self-confining via of this embodiment can be adapted to facilitate realization of complementary CMOS-type integrated circuits in two ways: (1) a vertical architecture that would employ integration between n- and p-device levels one above the other, and (2) a horizontally integrated architecture comprised of interleaved quantum wells.

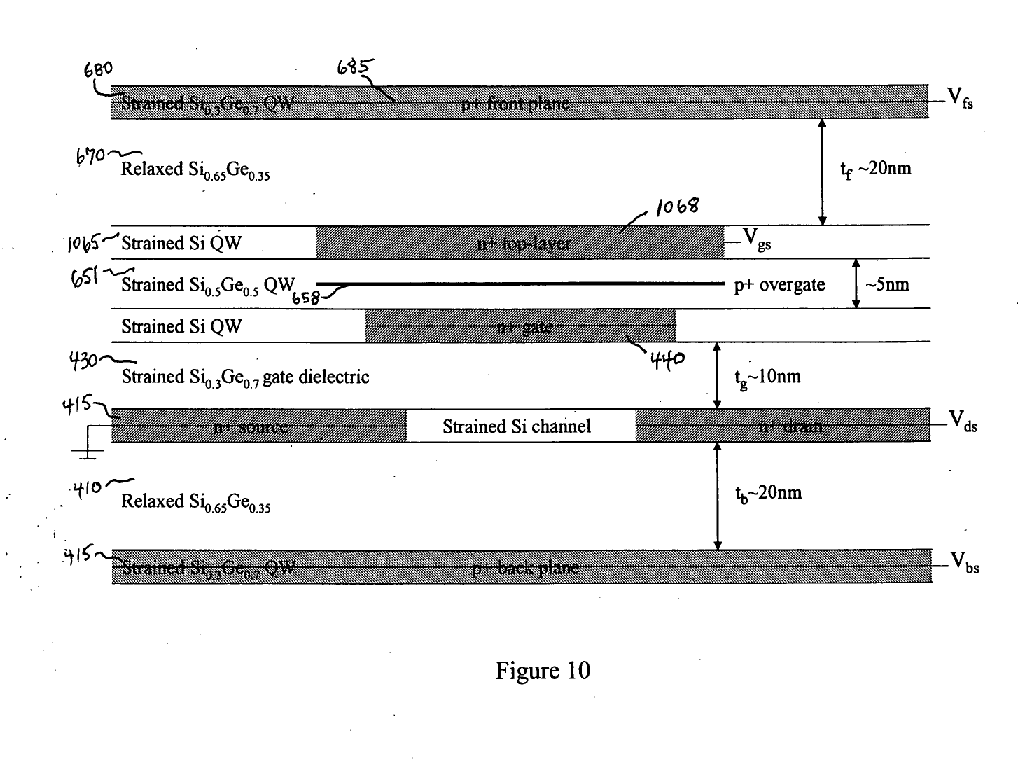

FIG. 10 illustrates a second fully-epitaxial embodiment of the invention that is more compact and conducive to horizontal integration. Compared to FIG. 6, the different feature is to eliminate the tunnel via and to grow the p+ overgate 658 into the center of a strained Si_{0.50}Ge_{0.50} layer QW 651 of ˜5 nm thickness so as to establish electrical connection by interband tunneling between the n+ gate 440 and a n+ top-layer 1068 having the same dimensions as the p+ overgate. Said n+ top-layer is grown into a strained Si QW 1065, similar to the n+ interconnect layer 650 seen in FIG. 6. Again, spaced from the n+ top-layer by Si_{0.65}Ge_{0.35} layer 670, is a p+ front-plane 685, in a strained Si_{0.3}Ge_{0.7} layer 680, held at the same negative bias as the p+ back-plane 415, at −0.23V in the above example. All of the numerical estimates for n-FET device properties and confinement remain the same.

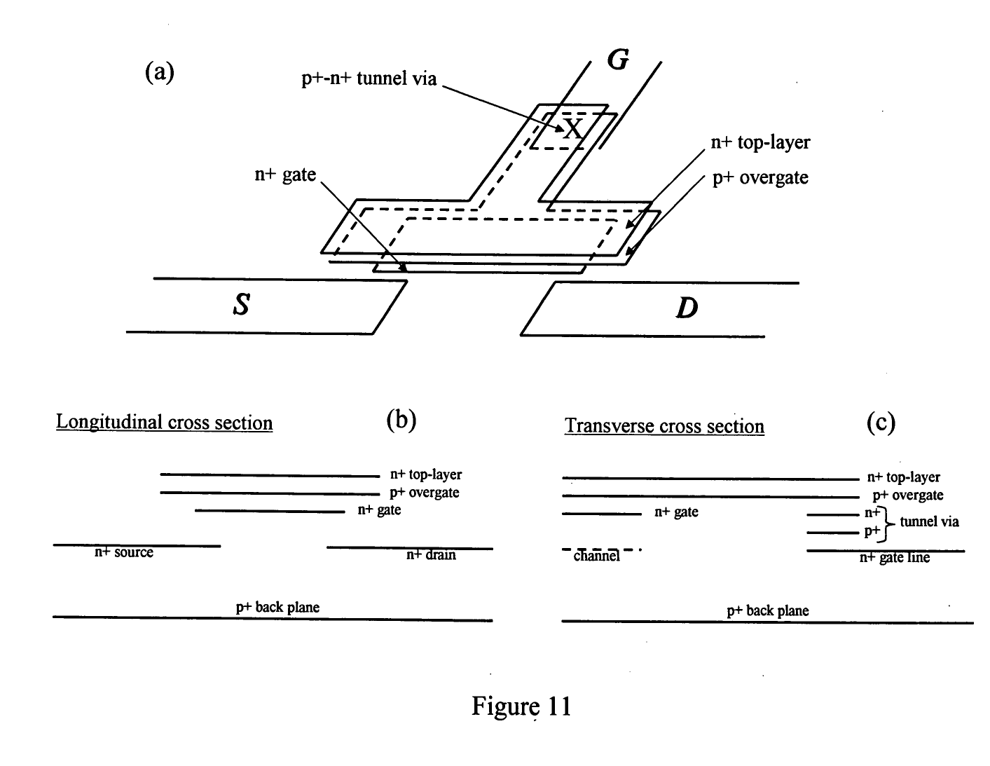

FIG. 11a illustrates further the complete gate structure for the second embodiment of the complete n-FET in perspective. In this embodiment of the invention, the gate line is patterned into the same strained Si quantum well that holds the source and drain. Here both the n+ top-gate and p+ overgate, having the same dimensions and vertically disposed, are extended outward from the channel to overlap the gate line, as indicated in the transverse cross section view of FIG. 11c. Electrical connection is achieved by inserting a two-level p+-n+ tunnel via between the n+ gate line and the p+ overgate. The p+ component of the tunnel via is grown into the center of the strained high-Ge Si_{0.3}Ge_{0.7} layer 430 that serves as the gate dielectric; and the n+ component of the via is patterned into the strained Si layer 440 along with the n+ gate.

Alternating n+ and p+ delta patterns of the same dimensions are again used to achieve a high degree of self-isolation. Identical n+ top-gate and p+ overgate patterns provide in-plane confinement for one another. Vertical confinement of ˜315 mV for holes below the p+ overgate is established over the transverse segment that spans the gap between the channel and the gate line, in addition to the source/drain overhang. With reference to FIG. 11c, it can be appreciated that large numbers of holes could be attracted downward by the negatively biased p+ back-plane in this gap region without a confining p-QW depth of ˜300 meV or greater.

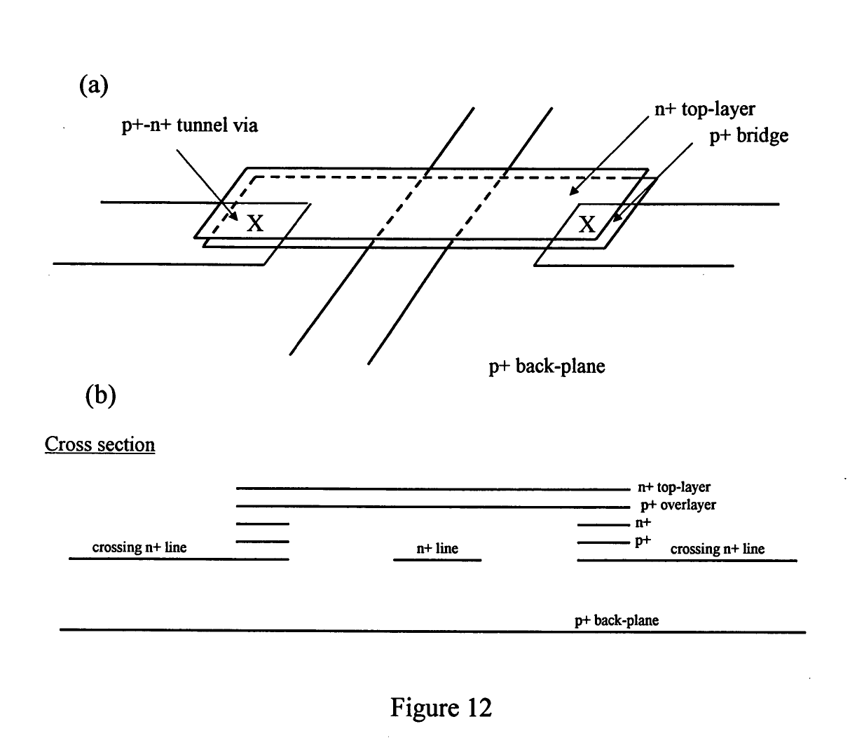

FIG. 12 illustrates a variation on the p+ overgate and n+ top-layer structure in FIG. 11c to implement line crossings at the source/drain/gate level. All local interconnections can be established by this means.

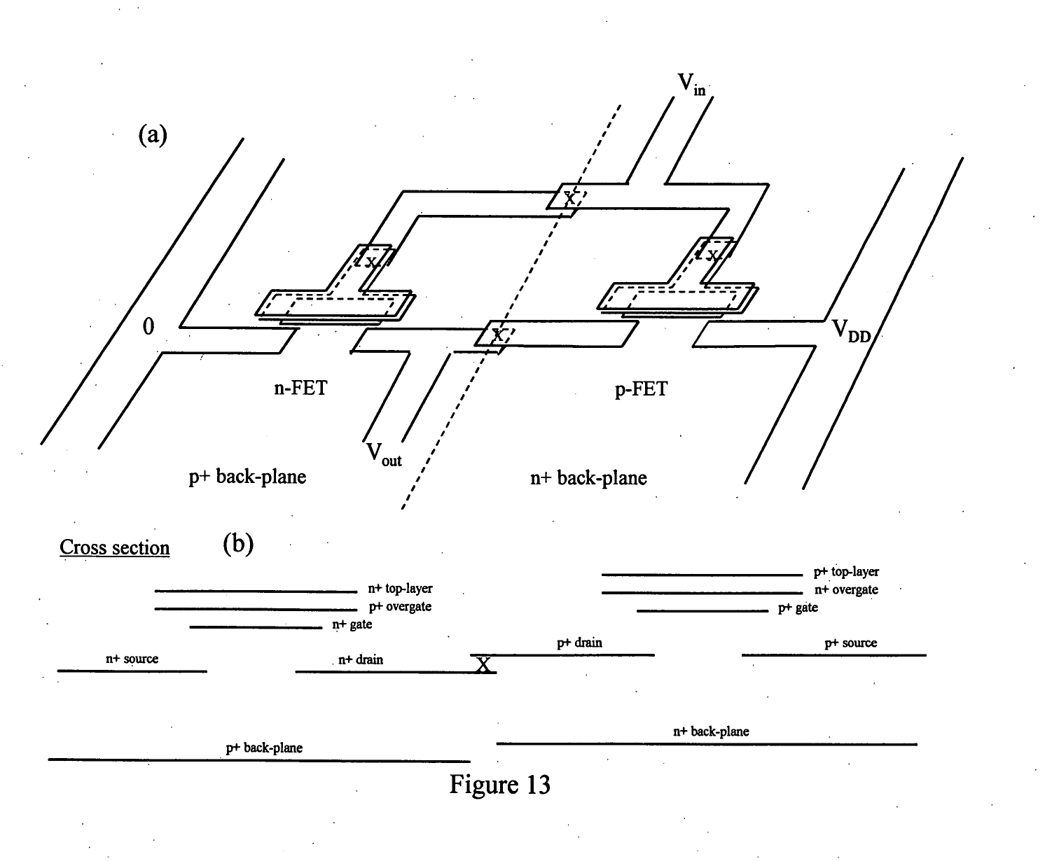

FIG. 13 illustrates one approach to implementing CMOS circuits by interleaving p- and n-type quantum wells. In cross section, it can be seen that the entire circuit is comprised of four levels of p+ and n+ planar delta-doping. Each delta-dopant layer is placed into a quantum well. Front-planes are not included here for simplicity. The front-planes of one layer may be the back-planes of the next in a multilevel architecture. Total thickness of each layer would be less than 100 nm.

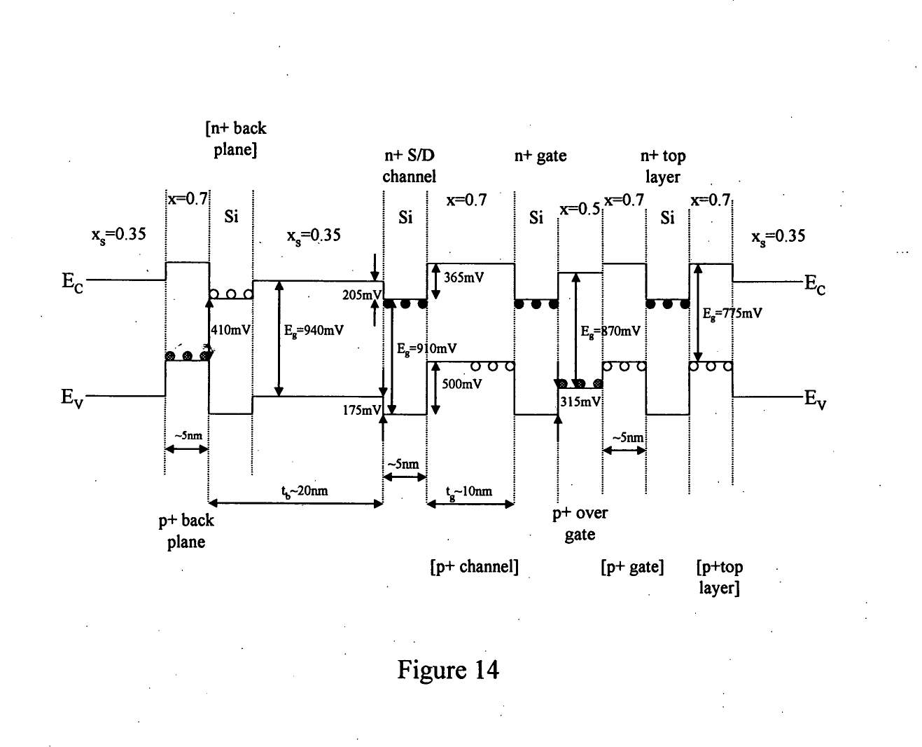

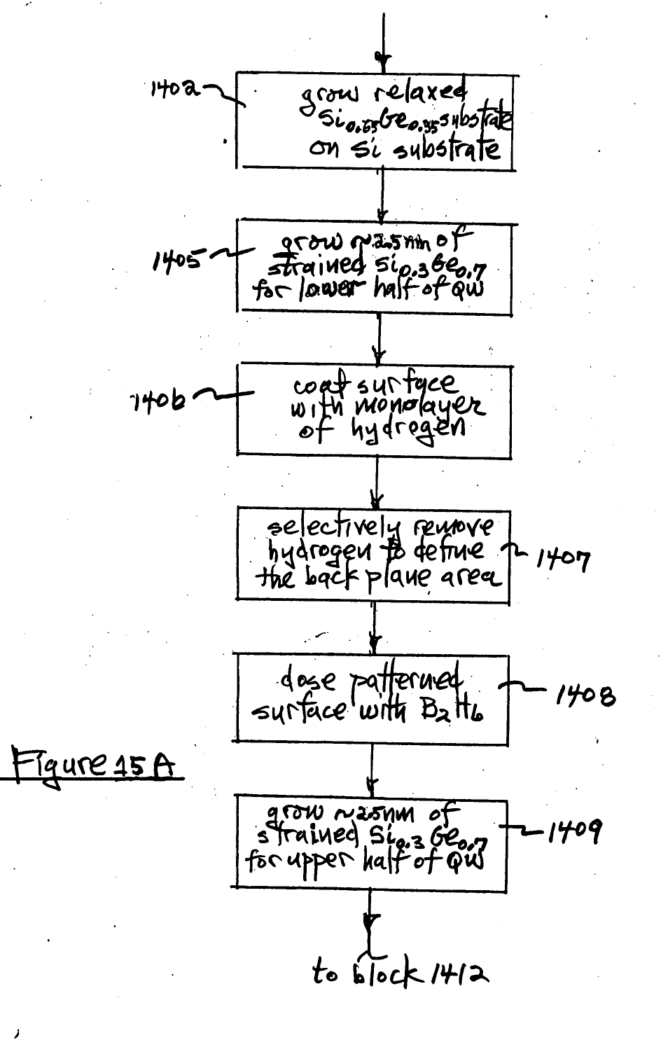

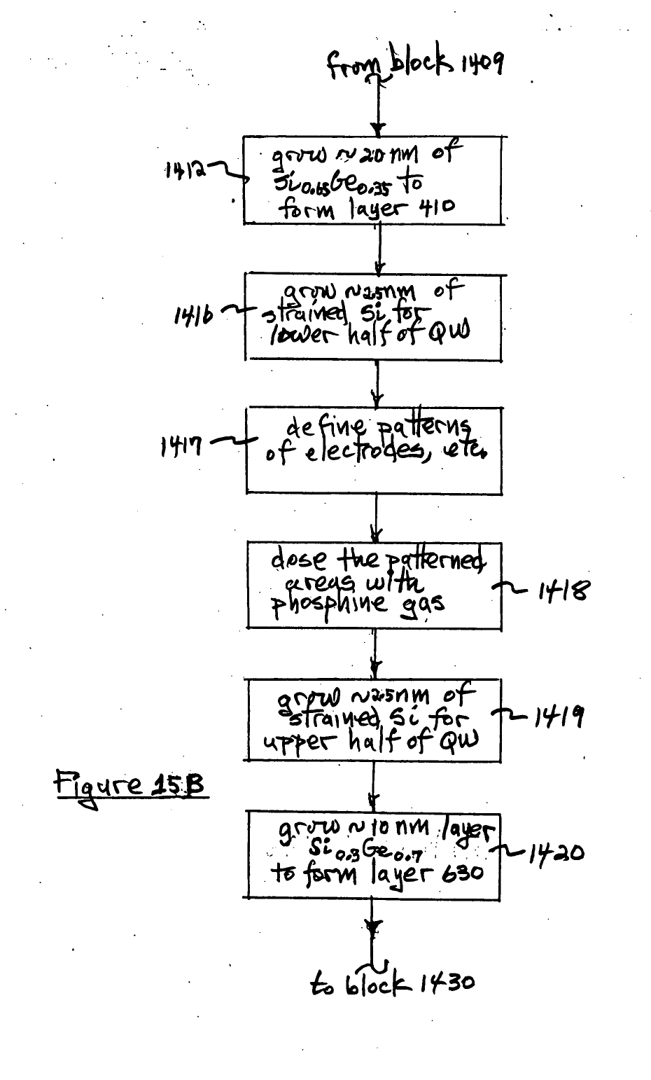

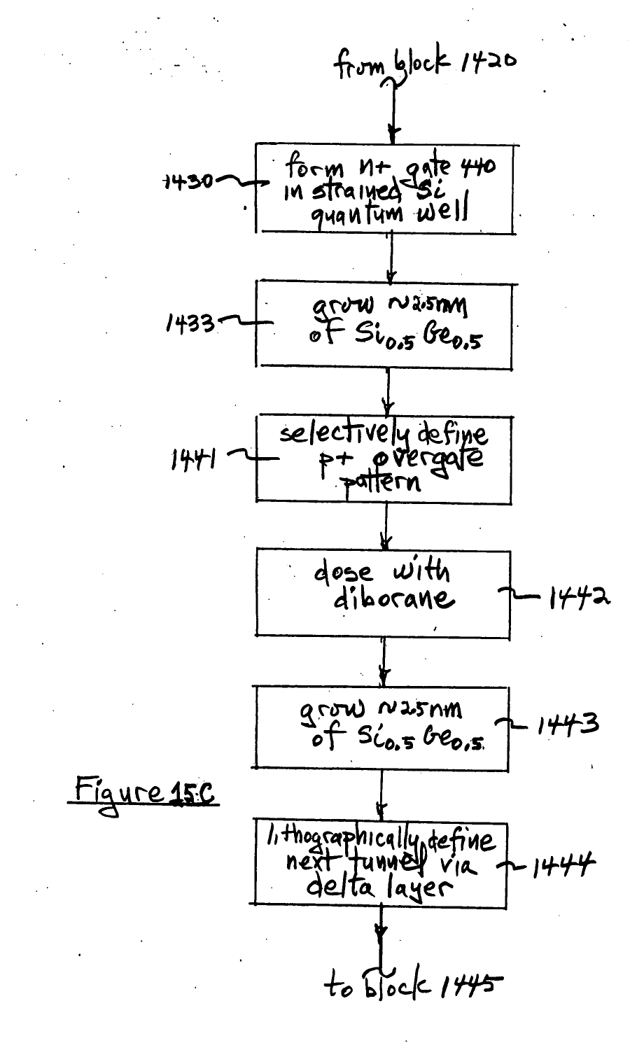

FIG. 14 shows the flat-band diagram for a series of interleaved p- and n-type quantum wells of the kind that would be employed. The layer labels and dopant indications are those of the n-FET. Doping for the p-FET is obtained by populating each adjacent well to the right with the complementary delta-dopant. As in other exemplary embodiments hereof, the virtual substrate is relaxed Si_{0.65}Ge_{0.35}, interleaved with strained Si n-QW's and strained Si_{0.3}Ge_{0.7} p-QW's together with a Si_{0.50}Ge_{0.50} p-well for the n-FET overgate. This structure can be further optimized, as numerous intertwined considerations are addressed based on more extensive material data and experimental devices.

A further consideration for all selectively delta-doped and interleaved quantum well architectures of this type is what to do with wandering carriers that escape the arrangements for confinement. One way to sink them would be to pattern tunnel vias at regular distances that go up from the supply rails to all of the quantum well layers. No additional doping layers would be needed to implement this in architectures similar to those depicted in FIGS. 11 and 13.

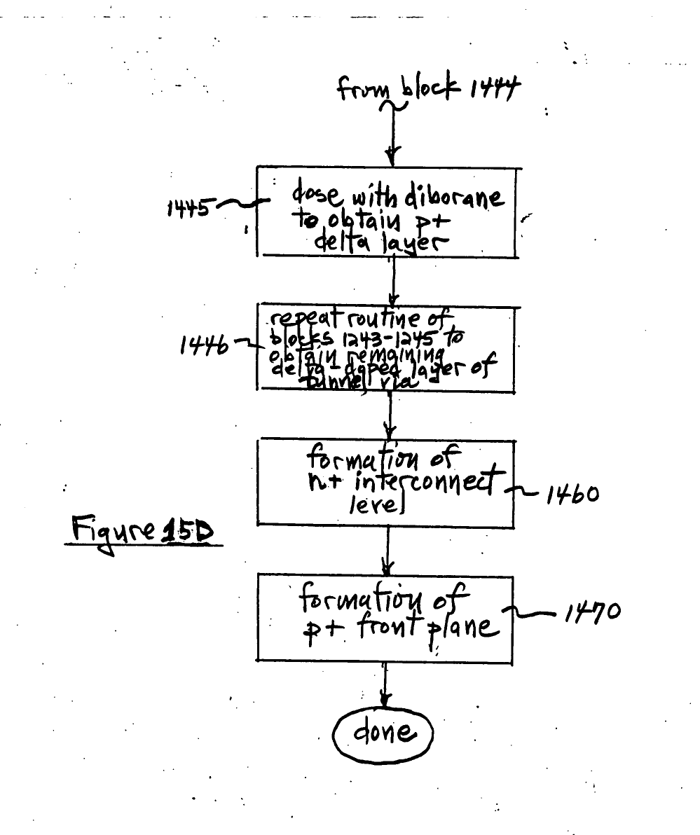

FIG. 15 is a flow diagram of an embodiment of a routine for fabricating the device of FIG. 6. (The reference to a single device is for ease of explanation, it being understood that multiple devices can be simultaneously fabricated side-by-side.) The block 1402 represents the growing of a relaxed Si_{0.65}Ge_{0.35} substrate 405 on a Si substrate, such as by low temperature CVD. The blocks 1405 through 1409 represent the formation of the p+ back-plane 415. First, as represented by block 1405, ˜2.5 nm of strained Si_{0.7}Ge_{0.7} is grown for the lower half of the quantum well. If necessary, the surface is coated (block 1406) with a monolayer of hydrogen. This can be done, for example, by exposing the crystal surface to hydrogen gas in the presence of a nearby hot filament to crack the H₂ molecules. However, if the prior growth was by CVD, the hydrogen monolayer will be present when growth is terminated, eliminating the need for this further step. Next, as represented by block 1407, hydrogen is selectively removed, lithographically, to define the back plane area. This can be implemented using any suitable technique, examples (also applicable at other places where lithography is referenced) being UV photolithography, low energy e-beam, and large STM/AFM scanned probe array. The patterned surface is then dosed with dilborane gas, B₂H₆ (block 1408), to a saturation coverage of ˜0.2 ML at room temperature. There is no adsorption on H-terminated areas. Then, as represented by block 1409, ˜2.5 nm of strained Si_{0.3}Ge_{0.7} is grown for the upper half of the p-type quantum well. A thicker ˜20 nm layer of the host material Si_{0.65}Ge_{0.35} is then grown (block 1412) to form the layer 410 of FIG. 6.

The blocks 1416 through 1419 represent the formation of the source/channel/drain (422, 428, 425) QW of FIG. 6. The block 1416 represents the growing of ˜2.5 nm of strained Si as the lower half of the quantum well. The block 1417 represents selectively defining, by lithography, the pattern of source and drain electrodes, their local interconnections, source ground, etc. Then, as represented by the block 1418, the surface is dosed with phosphine gas, PH₃, to a saturation ˜0.2 ML coverage within the patterned areas to obtain the n+ areas. Next, as represented by the block 1419, ˜2.5 nm of strained Si is grown for the upper half of the quantum well. A thicker ˜10 nm layer of strained Si_{0.3}Ge_{0.7} is then grown (block 1420) to form the gate barrier layer 430 to establish vertical confinement of electrons in the patterned n+ delta doped layer.

The block 1430 represents formation of the n+ gate level, comprising the n+ gate 440 in the strained Si quantum well of FIG. 6. This can be implemented using steps similar to those of 1416 through 1419, with appropriate patterning. The block 1433 represents the growing of ˜2.5 nm of strained Si_{0.5}Ge_{0.5}which is beneath the p+ overgate 658, followed by growth of the p+ overgate and tunnel via, represented by the blocks 1441-1446. The block 1441 represents selectively defining, lithographically, the p+ overgate pattern (658). This is followed by dosing with diborane (block 1442) and then growth of a thin ˜2.5 nm overlayer of Si_{0.5}Ge_{0.5} (block 1443). This is then followed by lighographicallly defining (block 1444) a smaller area for the first delta layer (652) of the tunnel via, and then dosing with diborane (block 1445) to obtain the p+ delta layer 653. The routine of blocks 1443-1445 is then repeated (block 1446) to form each of the further p+ delta layers, 653, 654, and 655 for the tunnel via. (For the via of FIG. 6, the delta layers will have alternating conductivity types.) A similar technique can be used to connect the source/drain and gate levels.

The block 1460 represents formation of the n+ interconnect level 665, which can use, for example, technique similar to that used for formation of the n+ source and drain level or the n+ gate level. Then, the block 1470 represents the formation of the p+ front plane (685), which can use, for example, technique similar to that used for formation of the p+ back plane.

The invention has been described with reference to particular preferred embodiments, but variations within the spirit and scope of the invention will occur to those skilled in the art. For example, it will be understood that suitable alternative material systems may be developed.

1. A field-effect transistor device, comprising:
a substrate;
a vertically stacked layered semiconductor structure on said substrate including the following layers: a first quantum well layer having laterally spaced-apart drain and source regions that are each delta doped with a dopant of a first conductivity type, said drain and source regions being laterally separated by a channel region; and a second quantum well layer vertically spaced from said first quantum well layer by a gate spacing layer, said second quantum well layer having a gate region, above the channel region, which is delta-doped with a dopant; and
electrical potentials being coupleable with respect to said source, drain, and gate regions.

2. The device as defined by claim 1, wherein said gate region is delta-doped with a dopant of said first conductivity type.

3. The device as defined by claim 1, further comprising a back plane layer beneath and vertically spaced from said first quantum well layer, said back plane layer being delta doped with a dopant of opposite conductivity type to said first conductivity type.

4. The device as defined by claim 2, wherein said back plane layer is a quantum well layer.

5. The device as defined by claim 1, wherein said first and second quantum well layers are strained layers.

6. The device as defined by claim 1, wherein said first and second quantum well layers each have a thickness of about 5 nm.

7. The device as defined by claim 1, wherein the delta doped drain and source regions are doped with a sheet of dopant having a physical thickness of about 1 nm.

8. The device as defined by claim 6, wherein the delta doped drain and source regions are doped with a sheet of dopant having a physical thickness of about 1 nm.

9. The device as defined by claim 3, wherein said first conductivity type is n-type and said opposite conductivity type is p-type.

10. The device as defined by claim 3, wherein said first conductivity type is p-type and said opposite conductivity type is n-type.

11. The device as defined by claim 1, wherein said first and second quantum well layers are strained Si layers in adjacent layers of SiₓGe₁₋ₓ.

12. The device as defined by claim 11, wherein at least some of the different ones of said adjacent layers have different compositions of SiₓGe₁₋ₓ, with x less than 1.

13. The device as defined by claim 1, wherein said substrate and the layers of said layered structure are layers of SiₓGe₁₋ₓ, with at least some of said layers having a composition with x less than 1.

14. The device as defined by claim 1, further comprising a third quantum well layer vertically spaced from said second quantum well layer, said third quantum well layer being delta doped with a dopant to form an interconnect layer, a gate control potential being coupleable with respect to said interconnect layer.

15. The device as defined by claim 14, wherein said third quantum well layer is spaced from said second quantum well layer by an interconnect tunneling region.

16. The device as defined by claim 15, wherein said interconnect tunneling region includes a plurality of tunneling vias.

17. The device as defined by claim 16, wherein said tunneling vias comprise a plurality of vertically spaced apart delta-doped regions.

18. The device as defined by claim 17, wherein said vertically spaced apart delta-doped regions are of the same conductivity type.

19. The device as defined by claim 17, wherein said vertically spaced apart delta-doped regions are of alternating conductivity types.

20. The device as defined by claim 15, wherein said third quantum well layer is doped with a dopant of the same conductivity type as the dopant of said gate layer.

21. The device as defined by claim 20, wherein said interconnect tunneling region further includes an overgate region disposed over said gate region, said overgate region being delta doped with a dopant of opposite conductivity type to the dopant of said gate region.

22. The device as defined by claim 14, further comprising a front plane layer above and vertically spaced from said interconnect layer.

23. The device as defined by claim 22, wherein said front plane layer is a fourth quantum well layer, delta doped with a dopant of opposite conductivity type to the conductivity type of said interconnect layer.

24. The device as defined by claim 14, wherein said gate control potential is applied via a gate conductor line in said first quantum well layer.

25. The device as defined by claim 24, wherein said gate conductor line is oriented transversely to said channel region.

26. The device as defined by claim 21, wherein said gate control potential is applied via a gate conductor line in said first quantum well layer.

27. The device as defined by claim 24, wherein said gate conductor line is oriented transversely to said channel region.

28. The device as defined by claim 27, wherein said overgate region has a lateral portion disposed over a portion of said gate conductor line.

29. A method for making a field-effect transistor device, comprising the steps of:
providing a substrate:
depositing, on said substrate, a vertically stacked layered semiconductor structure, including the following steps: depositing a back plane; depositing, vertically spaced from said back plane, a first quantum well layer having laterally spaced-apart drain and source regions that are each delta doped with a dopant of a first conductivity type, so that said drain and source regions are laterally separated by a channel region; depositing, vertically spaced from said first quantum well layer by a gate spacing layer, a second quantum well layer having a gate region, above the channel region, which is delta-doped with a dopant of said first conductivity type; and
providing couplings for applying electrical potentials with respect to said source, drain, and gate regions.

30. The method as defined by claim 29, wherein said step of depositing a first quantum well layer having laterally spaced-apart drain and source regions that are each delta doped with a dopant of a first conductivity type, so that said drain and source regions are laterally separated by a channel region, includes the following steps:
depositing a host semiconductor layer on said back plane layer;
depositing an initial strained semiconductor layer on said host layer;
patterning source and drain region patterns on said initial strained semiconductor layer;
forming source and drain regions by selectively applying sheets of dopant to said source and drain region patterns; and
depositing a further strained semiconductor layer over said initial strained semiconductor layer.

31. The method as defined by claim 30, wherein said step of depositing a second quantum well layer having a gate region, above the channel region, which is delta-doped with a dopant of said first conductivity type, comprises:
depositing an initial strained semiconductor layer on said gate spacing layer;
patterning a gate region pattern on the initial strained semiconductor layer on said gate spacing layer;
forming said gate region by selectively applying a sheet of dopant to said gate region pattern; and
depositing a further strained semiconductor layer over the initial strained semiconductor layer on said gate spacing layer.

32. A method for making a multiplicity of field-effect transistor devices, comprising the steps of:
providing a substrate a substrate;
depositing, on said substrate, a vertically stacked layered structure, including the following steps: depositing a back plane; depositing, vertically spaced from said ground plane, a first quantum well layer having a multiplicity of laterally spaced-apart pairs of drain and source regions that are each delta doped with a dopant of a first conductivity type, so that each said pair of drain and source regions are laterally separated by respective ones of a multiplicity of channel regions; depositing, vertically spaced from said first quantum well layer by a gate spacing layer, a second quantum well layer having a multiplicity of gate regions, above the respective multiplicity of channel regions, which are each delta-doped with a dopant of said first conductivity type; and
providing couplings for applying electrical potentials with respect to said source, drain, and gate regions.

33. The method as defined by claim 32, wherein said layered structure comprises pairs of complementary n-FETs and p-FETs.
